(19) United States
(12) Patent Application Publication
(10) Pub. No.: US 2026/0153574 A1
(43) Pub. Date: Jun. 4, 2026

(54) METHOD FOR PRODUCING A MAGNETIC SENSOR

(71) Applicant: Robert Bosch GmbH, Stuttgart (DE)

(72) Inventors: Corinna Koepernik, Reutlingen (DE); Heribert Weber, Nuertingen (DE)

(21) Appl. No.: 19/123,250

(22) PCT Filed: Oct. 16, 2023
(86) PCT No.: PCT/EP2023/078669

§ 371 Date: Apr. 22, 2025

(30) Foreign Application Priority Data
Nov. 7, 2022 (DE) 10 2022 211 730.1

(51) Int. Cl. G01R 33/09

(52) U.S. Cl. CPC G01R 33/09

(57) ABSTRACT

A method for producing a magnetic sensor. The method includes: arranging a first material having a first etch rate on a substrate to form a first layer; arranging a second material having a second etch rate on the first layer to form a second layer, the first etch rate being smaller than the second; arranging a third material on the second layer to form a third layer; structuring the third layer to create a structure having at least one open window in the third layer; etching, isotropically, the second layer through the at least one open window, as a result of which the third layer is undercut; after the through-etching of the second layer, the first layer is etched to create at least one inclined surface in the etched first layer, forming a magnetic sensing element on the at least one inclined surface of the first layer.

### FIELD

The present invention relates to a method for producing a magnetic sensor, and to a magnetic sensor.

### BACKGROUND INFORMATION

A common method for sensing Z-magnetic fields is the use of flux diverters. They are arranged in such a way that a magnetic field from the Z-direction is deflected in such a way that a portion of this field, as a field, reaches a sensing element that is sensitive in the plane. As a rule, these flux diverters consist of structures made of soft magnetic material. The production of such flux diverters is quite complex and is compatible with Semiconductor processes only to a limited extent. Furthermore, there is the disadvantage that strong external magnetic fields can change the magnetization of the flux diverters in such a way that the sensitivity of the overall system is affected and thus an offset arises. A further disadvantage is the contribution of the flux diverter to the signal noise and thus a reduction in the detectivity of the sensor.

### SUMMARY

An object of the present invention includes providing a concept that overcomes the above disadvantages.

This object may be achieved by means of certain features of the present invention. Advantageous embodiments of the present invention are disclosed herein.

According to a first aspect of the present invention, a method for producing a magnetic sensor is provided. According to an example embodiment of the present invention, the method comprises the following steps:
arranging a first material having a first etch rate on a substrate in order to form a first layer on the substrate, arranging a second material having a second etch rate on the first layer in order to form a second layer on the first layer, wherein the first etch rate is smaller than the second etch rate,
arranging a third material on the second layer in order to form a third layer on the second layer, wherein the third etch rate is in particular smaller than the first and second etch rates, in particular etch-resistant to an etching medium used, structuring the third layer in order to create a structure having at least one open window in the third layer, etching, in particular in an isotropic manner, the second layer through the at least one open window, as a result of which the third layer is undercut, wherein, after the through-etching of the second layer, the first layer is etched in order to create at least one inclined surface in the etched first layer, forming a magnetic sensing element on the at least one inclined surface of the first layer.

According to a second aspect of the present invention, a magnetic sensor is provided. According to an example embodiment of the present invention, the magnetic sensor comprises:
a substrate on which a first layer of a first material is formed, wherein the first material has a first etch rate, wherein a second layer of a second material is partially formed on the first layer, wherein the second material has a second etch rate,
wherein the first etch rate is smaller than the second etch rate,
wherein the first layer comprises, at least in certain areas in a region not covered by the second layer, at least one inclined surface on which a magnetic sensing element is formed.

The present invention is based on and includes the finding that the above object is achieved by using two materials that have different etch rates in an etching medium. Through the at least one open window in the third layer, the second layer is etched first by the isotropic etching process, wherein the third layer is undercut from the structure edges. After the through-etching of the second layer, the first layer is etched more slowly compared to the second layer, wherein the second layer acts as a laterally changing etch mask for the first layer. The etching of the second layer gradually exposes more and more of the surface of the first layer laterally, which has a slower etch rate both laterally and vertically than the changing etch mask formed by the etching of the second layer. As a result, one or more inclined surfaces are formed in the etched first layer, the inclination or angle of which in relation to the vertical perpendicular or orthogonal to the substrate surface can be set and/or influenced via the selected etch rate ratio between the first etch rate and the second etch rate.

This efficiently results in the technical advantage that at least one inclined surface can be efficiently created or formed in the first layer. The magnetic sensing element is formed on the at least one inclined surface so that it can measure or detect a Z-component of a magnetic field corresponding to the angle, without the need for a flux diverter.

The magnetic sensing element includes a stack of thin layers and is in particular an in-plane magnetic sensing element, i.e., it is in particular sensitive to magnetic fields parallel to its surface, i.e., parallel to the (thin) layers (designated as X or Y).

The above-described disadvantages of the related art can thus be overcome or avoided in an efficient manner.

Z-magnetic fields can thus be sensed efficiently, without the need for flux diverters.

The magnetic sensor thus has an intrinsic sensitivity to magnetic fields in the Z-direction.

The Z-direction or Z-axis runs orthogonally to the main surface/substrate surface of the substrate.

The substrate is, for example, a wafer, for example a Si wafer, i.e., a silicon wafer.

In one example embodiment of the method of the present invention, it is provided that the first material and/or the second material is in each case a dielectric.

This results in a technical advantage, for example, that materials that are particularly suitable with respect to their etch rate ratio can be used. The etching process can thus be performed efficiently.

In one example embodiment of the method of the present invention, it is provided that the first material is arranged on the substrate in such a way that the first layer has a first layer thickness, and wherein the second material is arranged on the first layer in such a way that the second layer has a second layer thickness, wherein the second layer thickness can be designed to be smaller than the first layer thickness.

This results in a technical advantage, for example, that the etching process can be performed efficiently. The first layer can, for example, be 10-30 times as thick as the second layer, which means that the first layer thickness can, for example, be 10-30 times greater than the second layer thickness. For example, the first layer thickness can be in the range of one or several μm.

In one example embodiment of the method of the present invention, it is provided that the first layer and the second layer consist of the same material, wherein the material of the first layer and the material of the second layer can in each case have different stoichiometric compositions and/or etch rates.

This results in a technical advantage, for example, that particularly suitable materials are used. In particular, this makes it possible for the etching process to be controlled or influenced in an advantageous and efficient manner so that the angle referred to above can be set or influenced efficiently.

In one example embodiment of the method of the present invention, it is provided that the first material and/or the second material can in each case comprise one or more of the following (group) elements selected from the following group of materials: SixOy, in particular SiO2, SixNy, in particular Si3N4, Si, in particular polycrystalline Si.

This results in a technical advantage, for example, that particularly suitable materials can be used.

The ratio of silicon to oxygen in the non-stoichiometric SixOy can be arbitrarily set within a certain range. This also allows the selectivity and thus the angle to be precisely adjusted.

In one example embodiment of the method of the present invention, it is provided that, after the creation of the inclined surface and prior to the formation of the magnetic sensing element on the inclined surface of the first layer, the third layer is removed.

This results in a technical advantage, for example, that the magnetic sensing element can be efficiently formed on the inclined surface.

In one example embodiment of the method of the present invention, it is provided that the third material is a photolithographic material so that a photolithographic layer is formed as the third layer, wherein the structuring of the third layer is performed by means of a photolithographic process.

In one example embodiment of the method of the present invention, the third material consists of an (in particular, different) etch-resistant material, a so-called hard mask. This hard mask has a lower etch rate than the first and second layers and can itself have been structured using a photolithographic process.

This results in a technical advantage, for example, that the third layer can be efficiently structured.

The hard mask itself is structured by means of a photolithographic process but can be more etch-resistant than a photoresist mask, especially in the case of long etching times and/or aggressive etching media.

The photolithographic material comprises, for example, a photoresist, in particular a negative resist or a positive resist.

The term “resist” can also be used for the term “photoresist.”

Statements made in connection with the method apply analogously to the magnetic sensor, and vice versa. This means that technical functionalities and technical features of the magnetic sensor according to the second aspect result analogously from corresponding technical functionalities and technical features of the method according to the first aspect, and vice versa.

The magnetic sensor according to the second aspect is or was produced, for example, by means of the method according to the first aspect.

For example, the third material has a third etch rate that is smaller than the second etch rate. For example, the third material has no etch rate. The third material is, for example, etch-resistant to the etching medium used for the first and second layers.

An etch rate within the meaning of the description refers in particular to a specific etching medium used for etching.

The magnetic sensing element is based, for example, on the AMR effect (anisotropic magnetoresistive effect) and/or the GMR effect (giant magnetoresistance effect) and/or the TMR effect (tunnel magnetoresistance effect).

The wording “at least one” means “one or more.”

If the singular is used for the magnetic sensing element, the plural is always implied, and vice versa. The same applies to the inclined surface. This means, for example, that one or more inclined surfaces, in particular two or more inclined surfaces, can be formed in the first layer. This means, for example, that one or more magnetic sensing elements can be formed on the one or more inclined surfaces. This means, for example, that one or more magnetic sensing elements can be formed in each case on one or more inclined surfaces.

An inclined surface within the meaning of the description is, for example, a planar surface. For example, an inclined surface within the meaning of the description comprises a planar portion. For example, the magnetic sensing element is formed on the planar surface or on the planar portion.

Due to the etching of the first layer, a recess is formed in the first layer, for example. This recess comprises, for example, at least one inclined side wall and/or a first inclined surface.

Etching within the meaning of the description is or comprises, for example, wet etching. For example, an isotropic dry etching method can be used.

The first layer of the magnetic sensor comprising, at least in certain areas in a region not covered by the second layer, an inclined surface on which a magnetic sensing element is formed means, in other words, that the first layer comprises, at least partially in a region not covered by the second layer, an inclined surface on which a magnetic sensing element is formed.

In one example embodiment of the method of the present invention, it is provided that the third material is a different material that is etch-resistant to an etching medium used, so that an etch-resistant layer is formed as the third layer, wherein the structuring of the third layer is performed by means of a photolithographic process.

In one example embodiment of the method of the present invention, it is provided that the first material and the second material are formed from the same chemical elements. This means that the first material and the second material do not comprise a different chemical element.

In one example embodiment of the method of the present invention, it is provided that the first material and the second material in each case have identical stoichiometric compositions, wherein the first material and the second material comprise at least one different chemical element.

The present invention is explained in more detail below using preferred exemplary embodiments.

### BRIEF DESCRIPTION OF THE DRAWINGS

FIG. 1 shows a flow chart of a method for producing a magnetic sensor, according to an example embodiment of the present invention.

FIG. 2 to 8 show different points in time in a method for producing a magnetic sensor, according to an example embodiment of the present invention.

FIG. 9 shows a magnetic sensor, according to an example embodiment of the present invention.

In the following, the same reference signs can be used for identical features.

### DETAILED DESCRIPTION OF EXAMPLE EMBODIMENTS

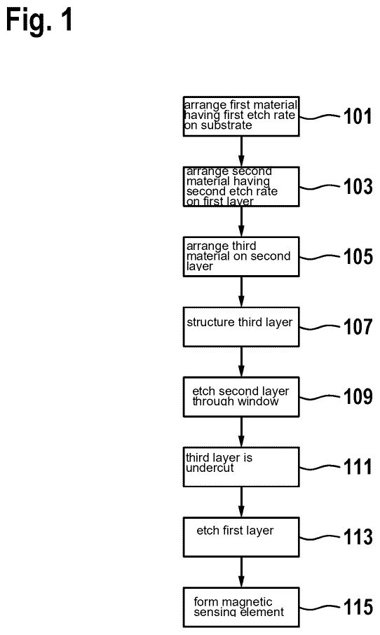

FIG. 1 shows a flow chart of a method for producing a magnetic sensor, comprising the following steps:
arranging 101 a first material having a first etch rate on a substrate in order to form a first layer on the substrate, arranging 103 a second material having a second etch rate on the first layer in order to form a second layer on the first layer, wherein the first etch rate is smaller than the second etch rate (for a specific etching medium),
arranging 105 a third material on the second layer in order to form a third layer on the second layer,
structuring 107 the third layer in order to create a structure having at least one open window in the third layer, in which the material of the third layer has been completely removed,
etching 109, in particular in an isotropic manner, the second layer through the at least one open window (using the specific etching medium), as a result of which the third layer is undercut 111, wherein, after the through-etching of the second layer, the first layer is etched 113 in order to create, at least in certain areas, i.e., partially, at least one inclined surface in the etched first layer,
forming 115 a magnetic sensing element on the at least one inclined surface of the first layer.

For example, at least one magnetic sensing element is created on the at least one inclined surface of the first layer.

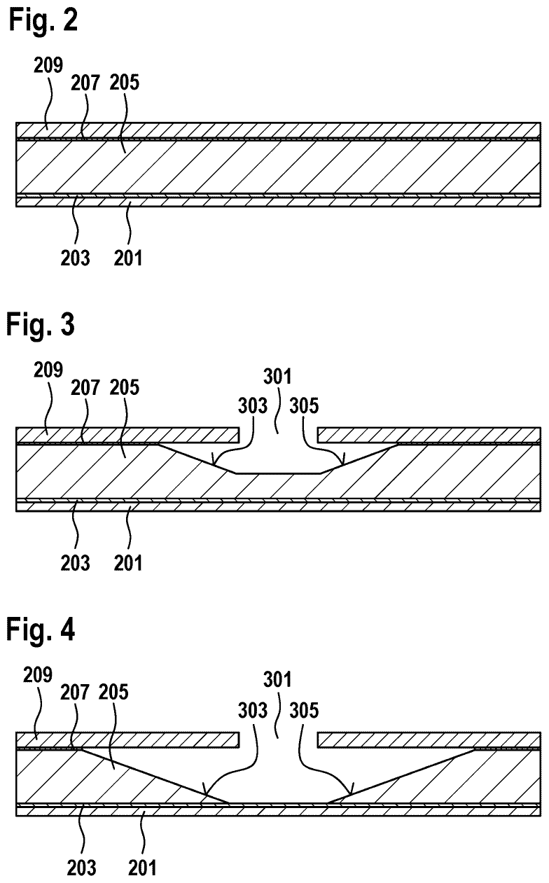

FIG. 2 shows a wafer 201 as an example of a substrate within the meaning of the description. The wafer 201 comprises a structural layer 203, which can contain a plurality of structures, for example conductor tracks, electrical contacts, and/or further electrical and/or mechanical functional elements.

A first layer 205 of a first material is formed on the wafer 201. A second layer 207 of a second material is formed on the first layer 205. The first material has a first etch rate. The second material has a second etch rate. The first etch rate is smaller than the second etch rate.

On the second layer 207, a photolithographic layer 209 of a photolithographic material is formed. The photolithographic layer 209 is an example of a third layer within the meaning of the description.

The first layer 205 has a first layer thickness, which is greater than a second layer thickness of the second layer 207.

The photolithographic layer 209, for example, is a resist, i.e., a photoresist.

The arrangement of layers shown in FIG. 2 is shown after structuring the photolithographic layer 209 by means of a photolithographic process in FIG. 3. Due to the structuring, the material of the photolithographic layer 209 is completely removed in a region of the photolithographic layer 209 and an open window 301 is formed in the photolithographic layer 209. Through this window 301, an etching process is performed. In detail, the second layer 207 is etched through the window 301, as a result of which the photolithographic layer 209 is undercut, wherein, after the through-etching of the second layer 207, the first layer 205 is etched in order to create two inclined surfaces in the etched first layer: a first inclined surface 303 and a second inclined surface 305. Based on the shape of the open window 301, for example, further inclined surfaces can be created in the first layer 205 in the etching process. It is noted that, in an embodiment not shown, it can be provided that only one inclined surface, the first or the second surface 303, 305, is created. In an embodiment not shown, more than two inclined surfaces can be created.

By providing a specific etching time, it is possible to influence the depth of the recess formed in the first layer 205 by the etching process.

This recess comprises, for example, two inclined side walls: the first inclined surface 303 and the second inclined surface 305.

The arrangement of layers shown in FIG. 3 is shown at the end of the etching process in FIG. 4. For example, etching can stop on material with very low or no etch rate. In the present case, the etching process stops at the wafer 201, more precisely at the structural layer 203.

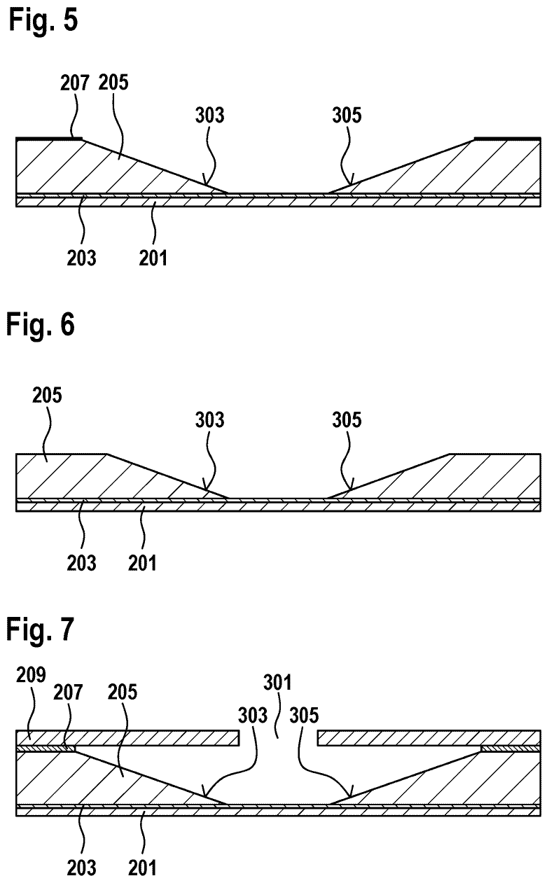

The arrangement of layers shown in FIG. 4 is shown after removal of the photolithographic layer 209 in FIG. 5.

The arrangement of layers shown in FIG. 5 is shown after removal of the second layer 207 in FIG. 6. The removal comprises, for example, a chemical-mechanical polishing or a selective etching process.

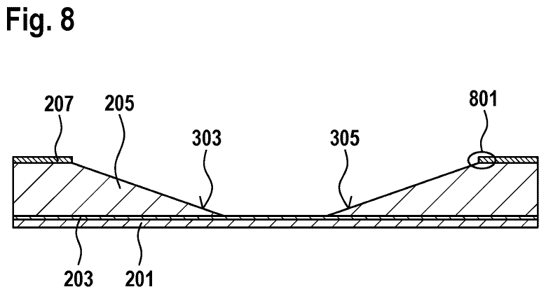

FIG. 7 shows a point in time at the end of an etching process analogous to FIG. 4, wherein the difference is that the second layer thickness of the second layer 207 according to FIG. 7 is greater than the second layer thickness of the second layer 207 shown in FIG. 4. If such a higher layer thickness is used, a step with a steeper edge can additionally be created after removal of the photolithographic layer 209, which is indicated in FIG. 8 by an oval with reference sign 801. Residues of the second layer 207 remain on the first layer 205.

An advantage of the method is in particular that the resulting angle is independent of the layer thickness of the second layer 207 (as long as it is significantly thinner than the first layer 205). This advantageously increases process control.

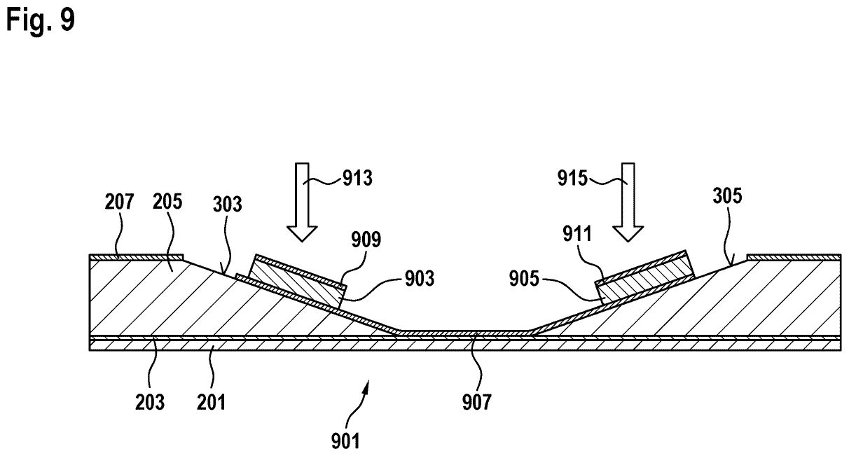

FIG. 9 shows a magnetic sensor, which was produced using the layer arrangement shown in FIG. 8. A first magnetic sensing element 903 was formed on the first inclined surface 301. A second magnetic sensing element 905 was formed on the second inclined surface 305. From below, the two magnetic sensing elements 903, 905 are electrically contacted by a common electrically conductive contacting layer 907, a so-called bottom electrode. The bottom electrode does not have to be continuous. From above, the two magnetic sensing elements 903, 905 in each case comprise their own electrically conductive contacting layer 909, 911, a so-called top electrode, for electrically contacting the corresponding magnetic sensing element 903, 905. In the same way, the top electrodes can also be continuous and the bottom electrodes can be led outward. In an embodiment not shown, the individual magnetic sensing elements 903, 905 can be contacted differently. For example, they can be suitably connected in series, parallel, or a combination of both.

Furthermore, FIG. 9 shows two arrows with reference signs 913, 915, which show an orientation of a magnetic field to be detected.

In summary, the concept described here can be used to efficiently create a tilted structure, the inclined surface. The method is based in particular on the creation of one or more inclined surfaces by means of a wet-chemical method that uses the different etch rates of silicon oxides with different silicon contents. On a silicon substrate, i.e., for example, on a silicon wafer, which can optionally contain other structures, for example, a thick SixOy layer with a low etch rate, i.e., for example, rich in silicon, can be deposited (first layer), followed by an optionally thin SiO2 layer (second layer) with a different, for example stoichiometric, material composition with a high etch rate. For example, a resist (third layer) is deposited on top and, for example, the desired structures (at least one open window) are created in a subsequent lithography process. A subsequent wet-chemical etching process subsequently etches, for example in an isotropic manner, first the thin stoichiometric SiO2 layer in the at least one open window structure, as a result of which the resist is undercut from structure edges, and, after the through-etching of the thin stoichiometric SiO2 layer, the thick Si-rich SixOy layer is etched at an etch rate that is smaller/lower than the etch rate of the stoichiometric layer, wherein the thin stoichiometric SiO2 layer can be regarded as a laterally changing etch mask. The etching of the thin layer gradually exposes more and more of the surface of the thick SixOy layer laterally, which isotropically has a slower etch rate/etch speed than the changing etch mask consisting of the second layer 207 of stoichiometric SiO2. This creates a uniform etched angle in the thick SixOy material of the first layer 205, the inclination of which can be set/influenced via the selected etch rate ratio between the fast-etching SiO2 layer and the slow-etching SixOy layer. The terms “thick” and “thin” here mean that the first layer has a greater layer thickness than the second layer. That is to say, the first layer has a first layer thickness and the second layer has a second layer thickness, wherein the first layer thickness is advantageously greater than the second layer thickness.

The inclined surfaces thus formed are used as a tilted base for one or more magnetic sensing elements. The concept described here uses, for example, two dielectric layers that etch at different rates.

The angle of the inclined surface in relation to, for example, a main surface/surface of the wafer or in relation to a vertical to the main surface/surface of the wafer can thus be very well controlled, i.e., set. This is in particular advantageous for use as a base for a magnetic sensing element that is intended to measure or sense a Z-component of a magnetic field to be detected. The angle has a direct influence on the sensitivity of such a measurement. Furthermore, the angle is crucial for further processing, for example the deposition of magnetic materials or the lithography on the inclined surface. The creation of the inclined surface can be exceptionally well controlled since the angle is almost exclusively determined by the etch rate ratio of the two dielectric layers used.

The selectivity is the quotient of the second etch rate and the first etch rate.

All types of reflow processes, for example for producing flat photoresist edges and/or isotropic etching processes, usually create a curved edge and thus not a flat/planar surface with a constant angle. The method described here, on the other hand, shows a constant angle to the wafer surface, i.e., to the main wafer surface, on a large portion of the flank (side wall of the recess). This means that a larger portion of the flank can be used for the sensing element and that the subsequent processes are significantly simplified.

At the same time, the transition from the flank (inclined surface) to the flat bottom surface can, for example, have a gentle rounding depending on the etch rates and/or the materials used, which is also advantageous for further processing.

Some reflow processes must be performed at high temperatures, which limits the use of an ASIC (application-specific integrated circuit) on the silicon substrate/silicon wafer. The method described here can advantageously be performed at low temperature.

One problem of using an ion beam etching process to create a flank, i.e., an inclined surface, is increased roughness of the etched surface. The wet etching process proposed here by way of example naturally has a very low surface roughness. This is particularly important and advantageous as a base surface for TMR sensing elements since a roughness in the order of magnitude of the thickness of the tunnel barrier (<≈2 nm) can already result in increased sensor noise.

Another problem of using an ion beam etching process is shadowing effects and the associated required spacing between the individual elements. The presented method can significantly increase the integration density, which leads to a reduction in costs.

1-10. (canceled)

11. A method for producing a magnetic sensor, comprising the following steps:
arranging a first material having a first etch rate on a substrate to form a first layer on the substrate;
arranging a second material having a second etch rate on the first layer to form a second layer on the first layer, wherein the first etch rate is smaller than the second etch rate;
arranging a third material on the second layer to form a third layer on the second layer;
structuring the third layer to create a structure having at least one open window in the third layer;
etching, in an isotropic manner, the second layer through the at least one open window, as a result of which the third layer is undercut;
after the through-etching of the second layer, etching the first layer to create at least one inclined surface in the etched first layer; and
forming a magnetic sensing element on the at least one inclined surface of the first layer.

12. The method according to claim 11, wherein the first material and/or the second material is a dielectric.

13. The method according to claim 11, wherein the first material is arranged on the substrate in such a way that the first layer has a first layer thickness, and wherein the second material is arranged on the first layer in such a way that the second layer has a second layer thickness, wherein the second layer thickness is smaller than the first layer thickness.

14. The method according to claim 11, wherein the first material and the second material have different stoichiometric compositions relative to one another.

15. The method according to claim 11, wherein the first material and the second material are formed from the same chemical elements.

16. The method according to claim 11, wherein the first material and the second material have identical stoichiometric compositions, and wherein the first material and the second material include at least one different chemical element relative to one another.

17. The method according to claim 11, wherein the first material and/or the second material includes one or more of the following elements selected from the following group of materials: SiO2, Si3N4, polycrystalline Si.

18. The method according to claim 11, wherein, after the creation of the inclined surface and prior to the formation of the magnetic sensing element on the inclined surface of the first layer, the third layer is removed.

19. The method according to claim 11, wherein the third material is a different material that is etch-resistant to an etching medium used, so that an etch-resistant layer is formed as the third layer, wherein the structuring of the third layer is performed using a photolithographic process.

20. A magnetic sensor, comprising:
a substrate on which a first layer of a first material is formed, wherein the first material has a first etch rate, a second layer of a second material is partially formed on the first layer, wherein the second material has a second etch rate, wherein the first etch rate is smaller than the second etch rate; and
a magnetic sensing element;
wherein the first layer includes, at least in certain areas in a region not covered by the second layer, at least one inclined surface on which the magnetic sensing element is formed.
